(19) United States
(12) Patent Application Publication
(10) Pub. No.: US 2026/0150521 A1
(43) Pub. Date: May 28, 2026

(54) DISPLAY PANEL AND DISPLAY APPARATUS

(71) Applicants: Hefei Visionox Technology Co., Ltd., Hefei (CN); Visionox Technology Inc., Kunshan (CN)

(72) Inventors: Zhiwei ZHOU, Hefei (CN); Yingyu FENG, Kunshan (CN); Jinfang ZHANG, Hefei (CN); Yang YANG, Hefei (CN); Lu ZHANG, Kunshan (CN)

(73) Assignees: Hefei Visionox Technology Co., Ltd., Hefei (CN); Visionox Technology Inc., Kunshan (CN)

(21) Appl. No.: 19/396,262

(22) Filed: Nov. 20, 2025

(30) Foreign Application Priority Data
Nov. 25, 2024 (CN) 202411699576.1
Nov. 29, 2024 (CN) 202411754120.0

(51) Int. Cl. H10K 59/122; H10K 59/35

(52) U.S. Cl. CPC H10K 59/122; H10K 59/353

(57) ABSTRACT

The present application discloses a display panel and a display apparatus. The display panel includes a substrate, a pixel defining layer, and light-emitting devices. A plurality of pixel openings include first pixel openings. An edge of the first pixel opening includes a first straight portion extending in a first direction and a recessed portion recessed toward the first straight portion. The recessed portion includes a second straight portion close to the first straight portion, the first pixel opening has a first dimension in a second direction which intersects with the first direction. A length of the second straight portion is less than the first dimension.

### CROSS-REFERENCE TO RELATED APPLICATIONS

The present application claims priority to Chinese Patent Application No. 202411754120.0, titled “DISPLAY PANEL AND DISPLAY APPARATUS” and filed on Nov. 29, 2024, and claims priority to Chinese Patent Application No. 202411699576.1, titled “DISPLAY PANEL AND DISPLAY APPARATUS” and filed on Nov. 25, 2024, which are hereby incorporated by reference in its entirety.

### FIELD

The present application relates to the field of display, and in particular to a display panel and a display apparatus.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

However, the performance of conventional OLED display products needs to be improved.

During the preparation of conventional OLED display panels, light-emitting pixel patterning is usually implemented by means of a fine metal mask (FMM). FMM technology is mature and has rich experience in mass production. However, FMM technology also has problems such as limited accuracy, and high costs. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN118251982A, CN115666161A, CN116648095A, CN117062489A, CN118678742A, CN118785761A, CN115224220A, CN118678729A, CN118660529A and CN118660589A.

### SUMMARY

An embodiment of the present application provides a display panel. The display panel includes: a substrate; a pixel defining layer disposed on one side of the substrate, the pixel defining layer having a plurality of pixel openings, the plurality of pixel openings including a plurality of first pixel openings, an edge of the first pixel opening including a first straight portion extending in a first direction and a recessed portion recessed toward the first straight portion, the recessed portion including a second straight portion close to the first straight portion, the first pixel opening having a first dimension in a second direction which intersects with the first direction, and a length of the second straight portion being less than the first dimension; and a plurality of light-emitting devices including a plurality of first light-emitting devices, part of the first light-emitting device being disposed in the corresponding first pixel opening.

An embodiment of the present application provides a display apparatus including a display panel, the display panel including: a substrate; a pixel defining layer disposed on one side of the substrate, the pixel defining layer having a plurality of pixel openings, the plurality of pixel openings including a plurality of first pixel openings, an edge of the first pixel opening including a first straight portion extending in a first direction and a recessed portion recessed toward the first straight portion, the recessed portion including a second straight portion close to the first straight portion, the first pixel opening having a first dimension in a second direction which intersects with the first direction, and a length of the second straight portion being less than the first dimension; and a plurality of light-emitting devices including a plurality of first light-emitting devices, part of the first light-emitting device being disposed in the corresponding first pixel opening.

The display panel according to the embodiments of the present application includes a substrate, a pixel defining layer, and light-emitting devices. The pixel defining layer has a plurality of pixel openings to define light-emitting regions of the display panel. A plurality of pixel openings include a plurality of first pixel openings. An edge of the first pixel opening includes a first straight portion extending in a first direction and a recessed portion recessed toward the first straight portion. The recessed portion includes a second straight portion close to the first straight portion. The first pixel opening is configured so two sides of the recessed portion in the first direction protrude in a direction away from the first straight portion, to increase an area of the first pixel opening, thereby increasing a light-emitting area of a light-emitting device and an aperture ratio of the display panel. A length of the second straight portion is less than a first dimension so the first pixel opening is recessed to a smaller extent toward the first straight portion, ensuring that the first pixel opening has a larger area, that is, the light-emitting device has a larger light-emitting area, thereby further improving the aperture ratio and the display effect of the display panel, and thus improving the performance of OLED display products.

### BRIEF DESCRIPTION OF THE DRAWINGS

FIG. 1 is a schematic partial top view of a display panel according to an embodiment of the present application;

FIG. 2 is a partial sectional view of a display panel according to an embodiment of the present application;

FIG. 3 is a schematic partial top view of a display panel according to another embodiment;

FIG. 4 is a schematic partial top view of a display panel according to still another embodiment;

FIG. 5 is a schematic partial top view of a display panel according to yet another embodiment;

FIG. 6 is a schematic partial top view of a display panel according to still yet another embodiment;

FIG. 7 is a schematic partial top view of a display panel according to a further embodiment;

FIG. 8 is a schematic partial top view of a display panel according to another further embodiment;

FIG. 9 is a partial sectional view of a display panel according to still another further embodiment;

FIG. 10 is a partial sectional view of a display panel according to yet another further embodiment;

FIG. 11 is a schematic partial top view of a display panel according to still yet another further embodiment;

FIG. 12 is a partial sectional view of a display panel according to a further embodiment;

FIG. 13 is a structural schematic diagram of layers of a display panel according to an embodiment of the present application;

FIG. 14 is a partial structural schematic diagram of a display panel according to an embodiment of the present application; and

FIG. 15 is a partial structural schematic diagram of a display panel according to another embodiment of the present application.

List of reference signs:
10. Display panel;
100. Substrate; 110. Drive circuit layer; 111. First pixel drive unit; 112. First via hole;
200. Isolation structure; 210. First layer; 220. Second layer; 230. Third layer; 240. Isolation opening;
300. Light-emitting device; 301. Lower electrode; 302. Light-emitting functional structure; 303. Upper electrode; 310. First light-emitting device; 311. First lower electrode; 320. Second light-emitting device; 330. Third light-emitting device; 340. Pixel; 350. First pixel column; 360. Second pixel column;
400. Pixel defining layer; 410. Pixel opening; 411. First pixel opening; 412. Second pixel opening; 413. Third pixel opening;
500. First straight portion; 510. Recessed portion; 511. Second straight portion; 512. Third straight portion; 513. First curved portion; 514. Fourth straight portion; 515. Second curved portion; 520. Fifth straight portion; 521. Sixth straight portion; 530. Third curved portion; 531. Fourth curved portion; 540. Seventh straight portion; 541. Fifth curved portion; 542. Sixth curved portion; 550. Eighth straight portion; 551. Seventh curved portion; 552. Eighth curved portion; 560. Ninth straight portion; 561. Ninth curved portion; 570. Tenth straight portion; 571. Tenth curved portion;
600. First encapsulation layer; 610. Encapsulation portion;
D1. First dimension; d1. First shortest distance; d2. Second shortest distance;
X. First direction; Y. Second direction.

### DETAILED DESCRIPTION OF THE EMBODIMENTS

Embodiments of the present application provide a display panel and a display apparatus. The embodiments of the display panel and the display apparatus will be described below with reference to the drawings.

The embodiments of the present application provide a display panel, which may be an organic light-emitting diode (OLED) display panel.

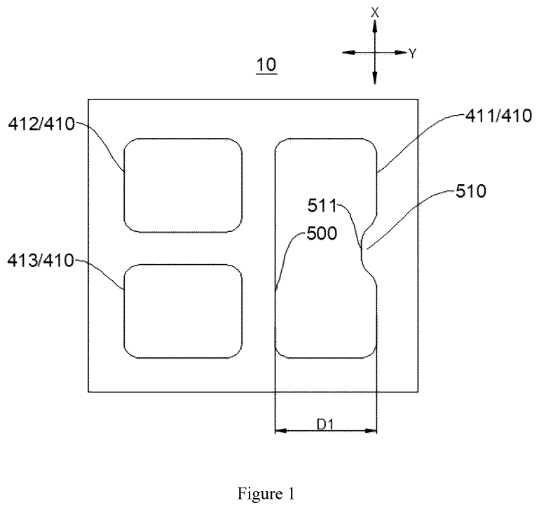

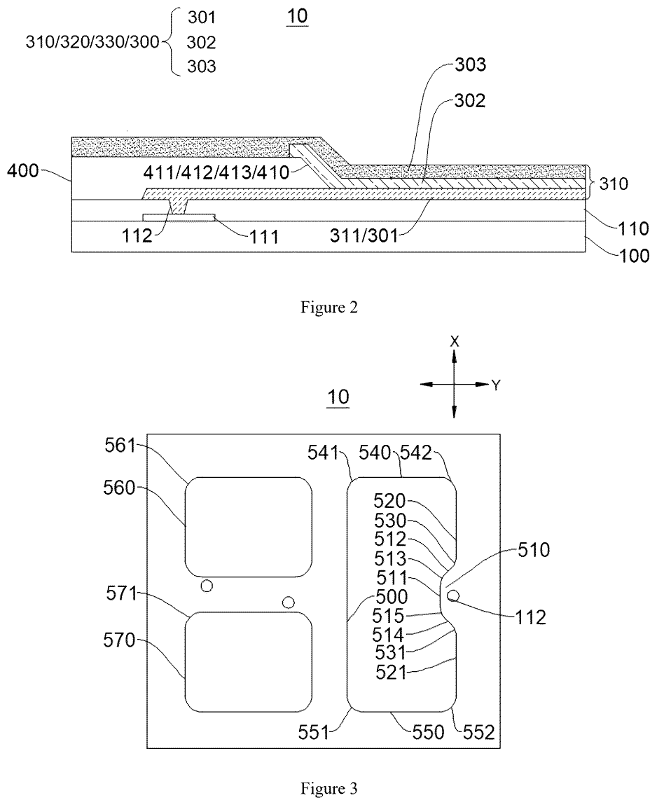

Referring to FIGS. 1 and 2 together, FIG. 1 is a schematic partial top view of a display panel according to an embodiment of the present application; and FIG. 2 is a partial sectional view of a display panel according to an embodiment of the present application.

As shown in FIGS. 1 and 2, an embodiment of the present application provides a display panel 10. The display panel 10 includes: a substrate 100; a pixel defining layer 400 disposed on one side of the substrate 100, the pixel defining layer 400 having a plurality of pixel openings 410, the plurality of pixel openings 410 including a plurality of first pixel openings 411, an edge of the first pixel opening 411 including a first straight portion 500 extending in a first direction X and a recessed portion 510 recessed toward the first straight portion 500, the recessed portion 510 including a second straight portion 511 close to the first straight portion 500, the first pixel opening 411 having a first dimension D1 in a second direction Y which intersects with the first direction X, and a length of the second straight portion 511 being less than the first dimension D1; and a plurality of light-emitting devices 300, the plurality of light-emitting devices 300 including a plurality of first light-emitting devices 310, part of the first light-emitting device 310 being disposed in the corresponding first pixel opening 411.

According to the display panel 10 of the embodiment of the present application, the display panel 10 includes the substrate 100, the pixel defining layer 400, and the light-emitting devices 300. The pixel defining layer 400 has a plurality of pixel openings 410 to define light-emitting regions of the display panel 10. The plurality of pixel openings 410 include the first pixel openings 411. The edge of the first pixel opening 411 includes the first straight portion 500 extending in the first direction X and the recessed portion 510 recessed toward the first straight portion 500. The recessed portion 510 includes the second straight portion 511 close to the first straight portion 500. The first pixel opening 411 is configured so two sides of the recessed portion 510 in the first direction X protrude in a direction away from the first straight portion 500, to increase an area of the first pixel opening 411, thereby increasing a light-emitting area of a light-emitting device and an aperture ratio of the display panel 10. The length of the second straight portion 511 is less than the first dimension D1 so the first pixel opening 411 is recessed to a smaller extent toward the first straight portion 500, ensuring that the first pixel opening 411 has a larger area, that is, the light-emitting device 300 has a larger light-emitting area, thereby further improving the aperture ratio and the display effect of the display panel 10, and thus improving the performance of OLED display products.

Referring to FIGS. 2 and 3, FIG. 3 is a schematic partial top view of a display panel according to another embodiment.

As shown in FIGS. 2 and 3, in some embodiments, the display panel further includes: a drive circuit layer 110 disposed between the substrate 100 and the pixel defining layer 400, the drive circuit layer 110 having a plurality of first pixel drive units 111 and a plurality of first via holes 112, the first light-emitting device 310 partially extending to the corresponding first via hole 112 and being electrically connected to the corresponding first pixel drive unit 111. At least part of the orthographic projection of the second straight portion 511 on the substrate 100 is located between an orthographic projection of the first straight portion 500 on the substrate 100 and an orthographic projection of the first via hole 112 on the substrate 100.

In these embodiments, the first light-emitting device 310 is electrically connected to the first pixel drive unit 111 by means of the first via hole 112, and the first pixel drive unit 111 drives the first light-emitting device 310, and the first light-emitting device 310 thus emits light. At least part of the second straight portion 511 is located between the first via hole 112 and the first straight portion 500, that is, at least part of the orthographic projection of the first via hole 112 on the substrate 100 is located within an orthographic projection of the pixel defining layer 400 on the substrate 100, and the pixel defining layer 400 is configured to cover at least part of the first via hole 112, thereby alleviating the problem of the arrangement of the first via hole 112 in the region of the first pixel opening 411 affecting the light emission of the first light-emitting device 310.

In one embodiment, the drive circuit layer 110 includes a planarization layer in which the first via hole 112 is formed.

In one embodiment, the first light-emitting device 310 includes a first lower electrode 311. The first lower electrode 311 partially extends to the corresponding first via hole 112 and is electrically connected to the corresponding first pixel drive unit 111, and the first pixel drive unit 111 provides a drive signal to the first lower electrode 311 to drive the first light-emitting device 310 to emit light.

In one embodiment, a part of the first lower electrode 311 is disposed between the drive circuit layer 110 and the pixel defining layer 400, and another part is exposed from the corresponding first pixel opening 411. Part of the first lower electrode 311 is exposed by the first pixel opening 411 to contact the light-emitting functional structure 302 of the first light-emitting device 310 to drive the light-emitting functional structure 302 to emit light.

In one embodiment, the orthographic projection of the pixel defining layer 400 on the substrate 100 covers the orthographic projection of the first via hole 112 on the substrate 100, avoiding the problem of the arrangement of the first via hole 112 in the region of the first pixel opening 411 affecting the light emission of the first light-emitting device 310.

In one embodiment, the first straight portion 500 is parallel to the second straight portion 511, that is, the second straight portion 511 extends in the first direction X, and the extension length of the second straight portion 511 in the first direction X is less than the first dimension D1.

In one embodiment, the first direction X is perpendicular to the second direction Y.

In some embodiments, the recessed portion 510 further includes a third straight portion 512 and a first curved portion 513. The first curved portion 513 is connected to a first end of the second straight portion 511 and a first end of the third straight portion 512, and an included angle between the second straight portion 511 and the third straight portion 512 is not less than 90 degrees.

In these embodiments, the included angle between the second straight portion 511 and the third straight portion 512 is not less than 90 degrees, and the dimension of the recessed portion 510 in the first direction X has a decreasing tendency in the second direction Y and toward the first straight portion 500, and the length of the second straight portion 511 is thus relatively small. The first pixel opening 411 is recessed to a smaller extent toward the first straight portion 500, ensuring that the first pixel opening 411 has a larger area, that is, the light-emitting device 300 has a larger light-emitting area, thereby further improving the aperture ratio and the display effect of the display panel 10, and thus improving the performance of OLED display products.

In some embodiments, the recessed portion 510 further includes a fourth straight portion 514 and a second curved portion 515. The second curved portion 515 is connected to a second end of the second straight portion 511 and a first end of the fourth straight portion 514, and an included angle between the second straight portion 511 and the fourth straight portion 514 is not less than 90 degrees.

In these embodiments, the included angle between the second straight portion 511 and the fourth straight portion 514 is not less than 90 degrees, and the dimension of the recessed portion 510 in the first direction X has a decreasing tendency in the second direction Y and toward the first straight portion 500, and the length of the second straight portion 511 is further reduced. The first pixel opening 411 is recessed to a smaller extent toward the first straight portion 500, ensuring that the first pixel opening 411 has a larger area, that is, the first light-emitting device 310 has a larger light-emitting area, thereby further improving the aperture ratio and the display effect of the display panel 10, and thus improving the performance of OLED display products.

In one embodiment, the third straight portion 512 and the fourth straight portion 514 are located on the side of the second straight portion 511 away from the first straight portion 500. The dimension of the recessed portion 510 in the first direction X is the spacing between the third straight portion 512 and the fourth straight portion 514 in the first direction X.

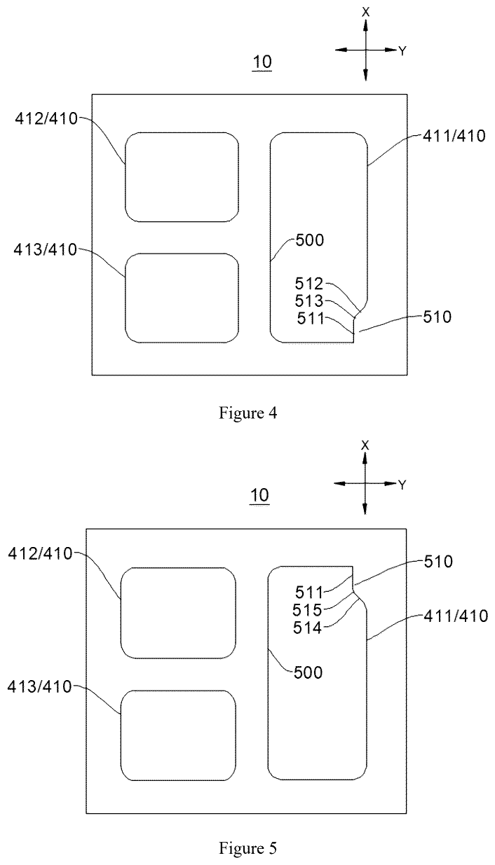

Referring to FIGS. 4 and 5 together, FIG. 4 is a schematic partial top view of a display panel according to still another embodiment; and FIG. 5 is a schematic partial top view of a display panel according to yet another embodiment.

As shown in FIGS. 4 and 5, optionally, the recessed portion 510 includes a second straight portion 511, a third straight portion 512, and a first curved portion 513. In one embodiment, the recessed portion 510 includes a second straight portion 511, a fourth straight portion 514, and a second curved portion 515. That is, the recessed portion 510 is provided at the corner of the first pixel opening 411.

As shown in FIGS. 1 to 3, optionally, the recessed portion 510 includes a second straight portion 511, a third straight portion 512, a first curved portion 513, a second straight portion 511, a fourth straight portion 514, and a second curved portion 515, that is, the recessed portion 510 is disposed at a position in the middle of the first pixel opening 411 in the first direction X.

In some embodiments, the edge of the first pixel opening 411 further includes a fifth straight portion 520 and a sixth straight portion 521, and the display panel 10 further includes: a drive circuit layer 110 disposed between the substrate 100 and the pixel defining layer 400, the drive circuit layer 110 having a plurality of first pixel drive units 111 and a plurality of first via holes 112, the first light-emitting device 310 partially extending to the corresponding first via hole 112 and being electrically connected to the corresponding first pixel drive unit 111. The fifth straight portion 520 and the sixth straight portion 521 are located on the side of the second straight portion 511 away from the first straight portion 500, and part of the orthographic projection of the first via hole 112 on the substrate 100 is located between an orthographic projection of the fifth straight portion 520 on the substrate 100 and an orthographic projection of the sixth straight portion 521 on the substrate 100.

In these embodiments, part of the orthographic projection of the first via hole 112 on the substrate 100 is located between the orthographic projection of the fifth straight portion 520 on the substrate 100 and the orthographic projection of the sixth straight portion 521 on the substrate 100, that is, the first via hole 112 is located at a position in the middle of the first pixel opening 411 in the first direction X, and the arrangement of the first via hole 112 below a portion of the pixel defining layer 400 forming the recessed portion 510 is facilitated, avoiding the problem of the arrangement of the first via hole 112 in the region of the first pixel opening 411 affecting the light emission of the first light-emitting device 310.

In some embodiments, the edge of the first pixel opening 411 further includes a third curved portion 530 and a fourth curved portion 531. The third curved portion 530 is connected to a second end of the third straight portion 512 and a first end of the fifth straight portion 520, an included angle between the third straight portion 512 and the fifth straight portion 520 is not less than 90 degrees, the fourth curved portion 531 is connected to a second end of the fourth straight portion 514 and a first end of the sixth straight portion 521, and an included angle between the fourth straight portion 514 and the sixth straight portion 521 is not less than 90 degrees.

In these embodiments, the included angle between the third straight portion 512 and the fifth straight portion 520 is not less than 90 degrees, and the dimension of the recessed portion 510 in the first direction X has a decreasing tendency in the second direction Y and toward the first straight portion 500, and the length of the second straight portion 511 is further reduced. The first pixel opening 411 is recessed to a smaller extent toward the first straight portion 500, ensuring that the first pixel opening 411 has a larger area, that is, the first light-emitting device 310 has a larger light-emitting area, thereby further improving the aperture ratio and the display effect of the display panel 10. The included angle between the fourth straight portion 514 and the sixth straight portion 521 is not less than 90 degrees, and the dimension of the recessed portion 510 in the first direction X has a decreasing tendency in the second direction Y and toward the first straight portion 500, and the length of the second straight portion 511 is further reduced. The first pixel opening 411 is recessed to a smaller extent toward the first straight portion 500, ensuring that the first pixel opening 411 has a larger area, that is, the first light-emitting device 310 has a larger light-emitting area, thereby further improving the aperture ratio and the display effect of the display panel 10.

In one embodiment, the fifth straight portion 520 is parallel to the first straight portion 500, and/or the fifth straight portion 520 is parallel to the first straight portion 500.

In some embodiments, the edge of the first pixel opening 411 further includes a seventh straight portion 540, a fifth curved portion 541, and a sixth curved portion 542. The fifth curved portion 541 is connected to a first end of the first straight portion 500 and a first end of the seventh straight portion 540, the sixth curved portion 542 is connected to a second end of the seventh straight portion 540 and a second end of the fifth straight portion 520, and the seventh straight portion 540 extends in the second direction Y.

In these embodiments, the first straight portion 500 and the seventh straight portion 540 are connected via the fifth curved portion 541 to allow a smooth transition at the intersection of the first straight portion 500 and the seventh straight portion 540, thereby alleviating the stress concentration generated at the intersection of the first straight portion 500 and the seventh straight portion 540.

In one embodiment, the length of the second straight portion 511 is less than the length of the seventh straight portion 540, and the length of the second straight portion 511 is further reduced. The first pixel opening 411 is recessed to a smaller extent toward the first straight portion 500, ensuring that the first pixel opening 411 has a larger area, that is, the first light-emitting device 310 has a larger light-emitting area, thereby further improving the aperture ratio and the display effect of the display panel 10.

In one embodiment, the length of the first straight portion 500 is greater than the length of the seventh straight portion 540, that is, the first via hole 112 is disposed close to the side of the first pixel opening 411 having a larger dimension, and the position of the first pixel opening 411 having a larger dimension facilitates the formation of a recess, making it easier for the first via hole 112 to be disposed below the recessed portion 510 of the pixel defining layer 400.

In some embodiments, an included angle between the seventh straight portion 540 and the first straight portion 500 is not less than 90 degrees, and/or an included angle between the seventh straight portion 540 and the fifth straight portion 520 is not less than 90 degrees.

In these embodiments, the included angle between the seventh straight portion 540 and the first straight portion 500 is not less than 90 degrees, and the angle formed by the first straight portion 500 and the seventh straight portion 540 is relatively large, thereby alleviating the problem of stress concentration at the intersection of the first straight portion 500 and the seventh straight portion 540 caused by a too small included angle between the seventh straight portion 540 and the first straight portion 500. The included angle between the seventh straight portion 540 and the fifth straight portion 520 is not less than 90 degrees, and the angle formed by the fifth straight portion 520 and the seventh straight portion 540 is relatively large, thereby alleviating the problem of stress concentration at the intersection of the fifth straight portion 520 and the seventh straight portion 540 caused by a too small included angle between the seventh straight portion 540 and the fifth straight portion 520.

In some embodiments, the edge of the first pixel opening 411 further includes an eighth straight portion 550, a seventh curved portion 551, and an eighth curved portion 552. The seventh curved portion 551 is connected to a second end of the first straight portion 500 and a first end of the eighth straight portion 550, the eighth curved portion 552 is connected to a second end of the eighth straight portion 550 and a second end of the sixth straight portion 521, and the eighth straight portion 550 extends in the second direction Y.

In these embodiments, the first straight portion 500 and the eighth straight portion 550 are connected via the seventh curved portion 551 to allow a smooth transition at the intersection of the first straight portion 500 and the eighth straight portion 550, thereby alleviating the stress concentration generated at the intersection of the first straight portion 500 and the eighth straight portion 550. The sixth straight portion 521 and the eighth straight portion 550 are connected via the eighth curved portion 552 to allow a smooth transition at the intersection of the sixth straight portion 521 and the eighth straight portion 550, thereby alleviating the stress concentration generated at the intersection of the sixth straight portion 521 and the eighth straight portion 550.

In one embodiment, the length of the second straight portion 511 is less than the length of the eighth straight portion 550, and the length of the second straight portion 511 is further reduced. The first pixel opening 411 is recessed to a smaller extent toward the first straight portion 500, ensuring that the first pixel opening 411 has a larger area, that is, the first light-emitting device 310 has a larger light-emitting area, thereby further improving the aperture ratio and the display effect of the display panel 10.

In one embodiment, the length of the first straight portion 500 is greater than the length of the eighth straight portion 550, that is, the first via hole 112 is disposed close to the side of the first pixel opening 411 having a larger dimension, and the position of the first pixel opening 411 having a larger dimension facilitates the formation of a recess, making it easier for the first via hole 112 to be disposed below the recessed portion 510 of the pixel defining layer 400.

In some embodiments, an included angle between the eighth straight portion 550 and the first straight portion 500 is not less than 90 degrees, and/or an included angle between the eighth straight portion 550 and the sixth straight portion 521 is not less than 90 degrees.

In these embodiments, the included angle between the eighth straight portion 550 and the first straight portion 500 is not less than 90 degrees, and the angle formed by the first straight portion 500 and the eighth straight portion 550 is relatively large, thereby alleviating the problem of stress concentration at the intersection of the first straight portion 500 and the eighth straight portion 550 caused by a too small included angle between the eighth straight portion 550 and the first straight portion 500. The included angle between the eighth straight portion 550 and the sixth straight portion 521 is not less than 90 degrees, and the angle formed by the sixth straight portion 521 and the eighth straight portion 550 is relatively large, thereby alleviating the problem of stress concentration at the intersection of the sixth straight portion 521 and the eighth straight portion 550 caused by a too small included angle between the eighth straight portion 550 and the sixth straight portion 521.

In one embodiment, the length of the seventh straight portion 540 is less than the first dimension D1, and/or the length of the eighth straight portion 550 is less than the first dimension D1. The length of the seventh straight portion 540 being less than the first dimension D1 ensures that the fifth curved portion 541 and the sixth curved portion 542 protrude in a direction away from the first pixel opening 411. The length of the eighth straight portion 550 being less than the first dimension D1 ensures that the seventh curved portion 551 and the eighth curved portion 552 protrude in the direction away from the first pixel opening 411.

Referring to FIGS. 1 and 3, in some embodiments, the plurality of pixel openings 410 further include a plurality of second pixel openings 412, and the plurality of light-emitting devices 300 further include a plurality of second light-emitting devices 320. An edge of the second pixel opening 412 includes a plurality of ninth straight portions 560 and a plurality of ninth curved portions 561. The ninth curved portion 561 is connected between two corresponding adjacent ninth straight portions 560, and an included angle between two adjacent ninth straight portions 560 is not less than 90 degrees. Part of the second light-emitting device 320 is disposed in the corresponding second pixel opening 412, and a light-emitting color of the second light-emitting device 320 is different from a light-emitting color of the first light-emitting device 310.

In these embodiments, two adjacent ninth straight portions 560 are connected via the ninth curved portion 561 to allow a smooth transition at the intersection of the two adjacent ninth straight portions 560 thereby alleviating the stress concentration generated at the intersection of the two adjacent ninth straight portions 560. The included angle between the two adjacent ninth straight portions 560 is not less than 90 degrees, and the angle formed by the two adjacent ninth straight portions 560 is relatively large, thereby alleviating the problem of stress concentration at the intersection of the two adjacent ninth straight portions 560 caused by an angle included between the two adjacent ninth straight portions 560 that is too small.

Referring to FIGS. 1 and 3, in some embodiments, the plurality of pixel openings 410 further include a plurality of third pixel openings 413, and the plurality of light-emitting devices 300 further include a plurality of third light-emitting devices 330. An edge of the third pixel opening 413 includes a plurality of tenth straight portions 570 and a plurality of tenth curved portions 571. The tenth curved portion 571 is connected between two corresponding adjacent tenth straight portions 570, and an included angle between two adjacent tenth straight portions 570 is not less than 90 degrees. Part of the third light-emitting device 330 is disposed in the corresponding third pixel opening 413, and the light-emitting color of the first light-emitting device 310, the light-emitting color of the second light-emitting device 320, and a light-emitting color of the third light-emitting device 330 are different from one another.

In these embodiments, two adjacent tenth straight portions 570 are connected via the tenth curved portion 571 to allow a smooth transition at the intersection of the two adjacent tenth straight portions 570 thereby alleviating the stress concentration generated at the intersection of the two adjacent tenth straight portions 570. The included angle between the two adjacent tenth straight portions 570 is not less than 90 degrees, and the angle formed by the two adjacent tenth straight portions 570 is relatively large, thereby alleviating the problem of stress concentration at the intersection of the two adjacent tenth straight portions 570 caused by an angle included between the two adjacent tenth straight portions 570 that is too small.

In one embodiment, the recessed portion 510 is located on a side of the first straight portion 500 away from the second pixel opening 412, and/or the recessed portion 510 is located on a side of the first straight portion 500 away from the third pixel opening 413.

In one embodiment, the length of the first straight portion 500 is greater than a length of the ninth straight portion 560, and/or the length of the first straight portion 500 is greater than a length of the tenth straight portion 570. The arrangement of the second light-emitting device 320 and the third light-emitting device 330 on one side of the first light-emitting device 310 in the second direction Y is facilitated, and the arrangement of the first light-emitting device 310, the second light-emitting device 320 and the third light-emitting device 330 is more uniform.

In one embodiment, an opening area of the first pixel opening 411 is greater than an opening area of the second pixel opening 412, and/or the opening area of the first pixel opening 411 is greater than an opening area of the third pixel opening 413.

In these embodiments, the area of the first pixel opening 411 being set to be larger can prolong the service life of the first light-emitting device 310, thereby avoiding the problem of a decrease in the display effect of the display panel 10 caused by the too fast brightness decay rate of the first light-emitting device 310.

In one embodiment, the light-emitting color of the first light-emitting device 310 is blue, the light-emitting color of the second light-emitting device 320 is either red or green, and the light-emitting color of the third light-emitting device 330 is the other one of red and green.

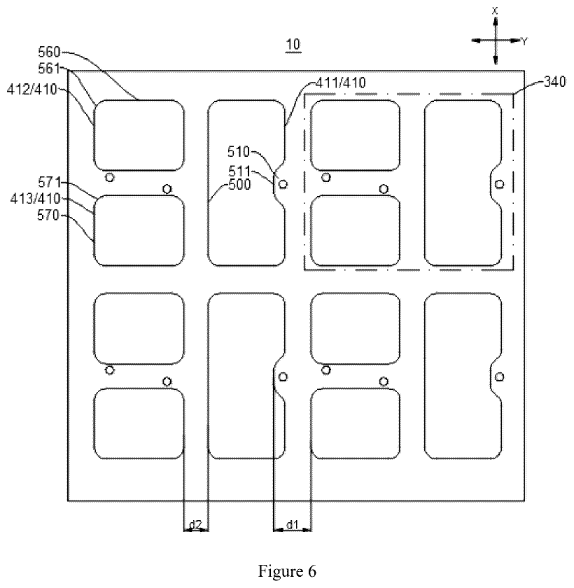

Referring to FIGS. 2 and 6 together, FIG. 6 is a schematic partial top view of a display panel according to still yet another embodiment.

As shown in FIGS. 2 and 6, optionally, the display panel 10 includes a plurality of pixels 340 arranged in an array, the pixel 340 including a first light-emitting device 310, a second light-emitting device 320 and a third light-emitting device 330. In the same pixel 340, the second light-emitting device 320 and the third light-emitting device 330 are arranged in the first direction X, and the second light-emitting device 320 and the third light-emitting device 330 are located on the same side of the third light-emitting device 330 in the second direction Y. The arrangement of the plurality of pixel 340 in an array improves the uniformity of the arrangement of the light-emitting devices 300 and improves the display effect of the display panel 10.

In some embodiments, the second straight portion 511 has a first shortest distance d1 from a ninth straight portion 560, which is close to the second straight portion 511, extends in the first direction X, and in a pixel 340 adjacent to the second straight portion in the second direction Y; and the first straight portion 500 has a second shortest distance d2 from a ninth straight portion 560, which is close to the first straight portion 500, extends in the first direction X, and in the same pixel 340, and the first shortest distance d1 being not less than the second shortest distance d2.

In these embodiments, the first shortest distance d1 is not less than the second shortest distance d2, that is, there is a greater spacing between the second straight portion 511 and the second pixel opening 412 in the adjacent pixel 340, and the arrangement of the first lower electrode 311 in a region between the second straight portion 511 and the second pixel opening 412 in the adjacent pixel 340 is facilitated, and it is possible to outwardly expand the first pixel opening 411 in a direction toward the adjacent pixel 340, that is, the first pixel opening 411 is configured so two sides of the recessed portion 510 in the first direction X protrude in a direction toward the adjacent pixel 340, to increase the area of the first pixel opening 411, thereby increasing the light-emitting area of the first light-emitting device 310 and the aperture ratio of the display panel 10.

In some embodiments, the length of the second straight portion 511 is less than or equal to one half of the first dimension D1.

In these embodiments, the length of the second straight portion 511 is less than or equal to one half of the first dimension D1, and the recessed part of the first pixel opening 411 is further reduced, further increasing the area of the first pixel opening 411. That is, the first light-emitting device 310 has a larger light-emitting area, further improving the aperture ratio and the display effect of the display panel 10.

In some embodiments, the length of the second straight portion 511 is less than or equal to one third of the length of the first straight portion 500.

In these embodiments, the length of the second straight portion 511 is less than or equal to one third of the length of the first straight portion 500, and the recessed part of the first pixel opening 411 is further reduced, further increasing the area of the first pixel opening 411. That is, the first light-emitting device 310 has a larger light-emitting area, further improving the aperture ratio and the display effect of the display panel 10.

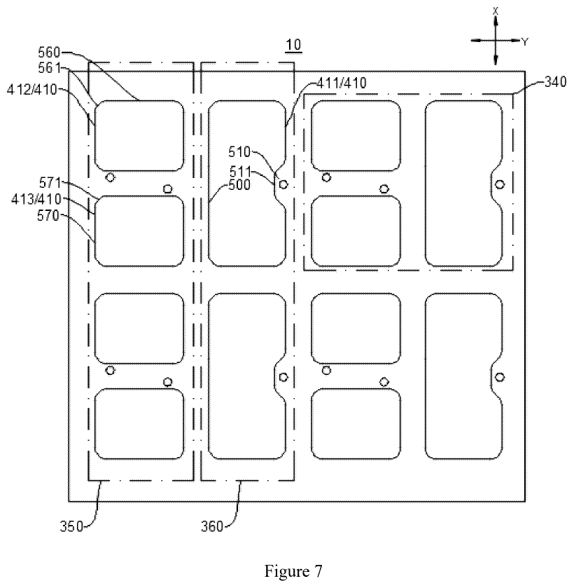

Referring to FIGS. 2 and 7 together, FIG. 7 is a schematic partial top view of a display panel according to a further embodiment.

As shown in FIGS. 2 and 7, in some embodiments, the display panel 10 includes a plurality of first pixel columns 350 and a plurality of second pixel columns 360 which are arranged alternately in the second direction Y. The first pixel column 350 includes a plurality of second light-emitting devices 320 and a plurality of third light-emitting devices 330 which are arranged alternately in the first direction X. The second pixel column 360 includes a plurality of first light-emitting devices 310 arranged in the first direction X. In one embodiment, in the first pixel column 350, the corresponding plurality of second pixel openings 412 and the corresponding plurality of third pixel openings 413 are arranged alternately in the first direction X; and in the second pixel column 360, the corresponding plurality of first pixel openings 411 are arranged in the first direction X.

In these embodiments, when the first light-emitting devices 310, the second light-emitting devices 320, and the third light-emitting devices 330 are arranged in this way, the first via hole 112 corresponding to the first light-emitting device 310 is disposed between the first light-emitting device 310 and the second light-emitting device 320, and the distance between the first light-emitting device 310 and the second light-emitting device 320 on a side of an adjacent first light-emitting device 310 facing away from the first via hole 112 corresponding to the first light-emitting device 310 can be reduced to increase the aperture ratio of the first light-emitting device 310.

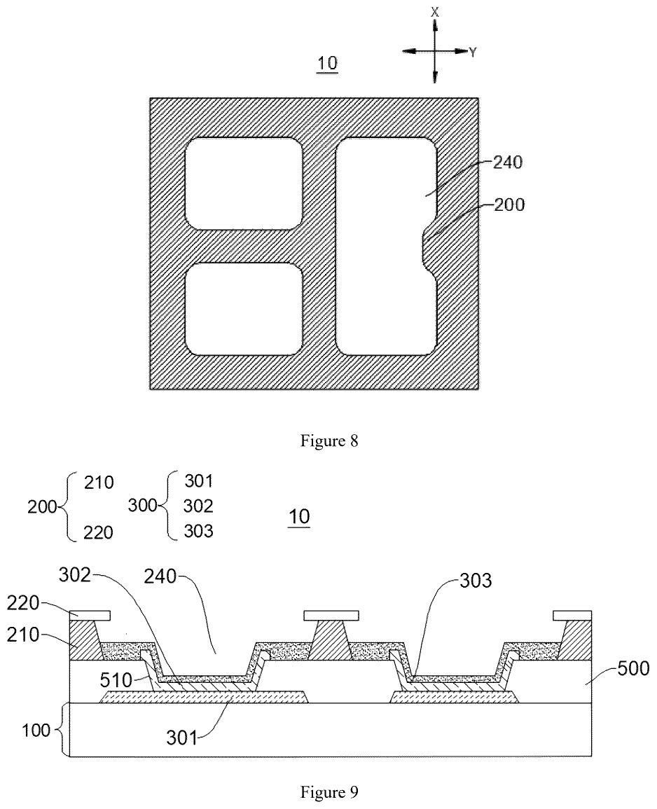

Referring to FIGS. 8 and 9, FIG. 8 is a schematic partial top view of a display panel according to another further embodiment; and FIG. 9 is a partial sectional view of a display panel according to still another further embodiment.

As shown in FIGS. 8 and 9, in some embodiments, the display panel further includes: an isolation structure 200 located on one side of the substrate 100. The isolation structure 200 encloses a plurality of isolation openings 240. The isolation opening 240 is in communication with the corresponding pixel opening 410.

In these embodiments, after the isolation structure 200 is provided, when the light-emitting device 300 is prepared, a light-emitting material layer has a large drop at an edge of the isolation structure 200, and is difficult to be continuous, resulting in breakage. The light-emitting material layer breaks to form light-emitting functional structures 302 located in the isolation openings 240, thereby reducing crosstalk of carriers in the light-emitting functional structures 302, and improving the display effect of the display panel 10. In addition, the light-emitting devices 300 can be prepared without the use of a precision mask, thereby reducing the development and use of the precision mask and lowering the preparation cost.

In one embodiment, the isolation structure 200 may be located on a side of the pixel defining layer 400 facing away from the substrate 100.

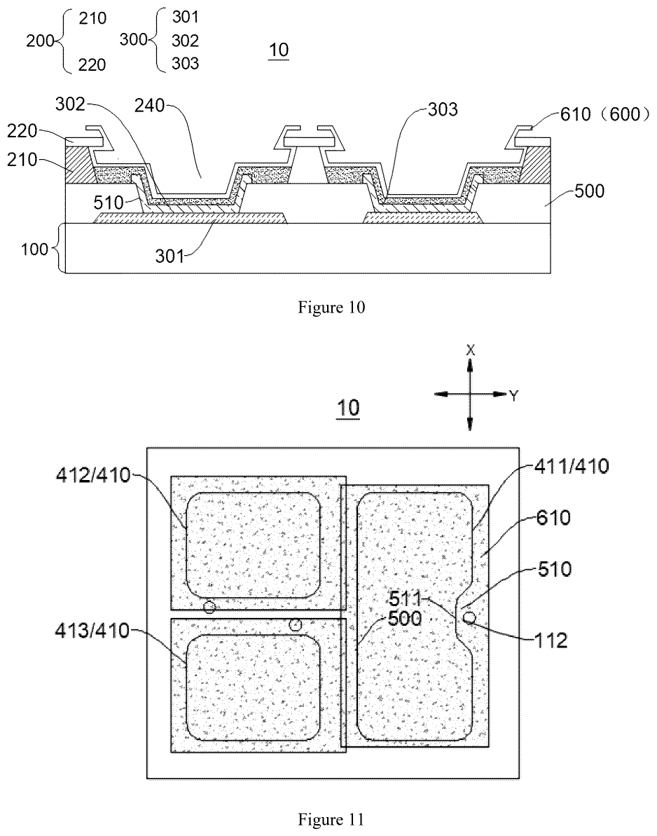

Referring to FIGS. 10 and 11, FIG. 10 is a partial sectional view of a display panel according to yet another further embodiment; and FIG. 11 is a schematic partial top view of a display panel according to still yet another further embodiment.

As shown in FIGS. 10 and 11, in some embodiments, the display panel 10 further includes: a first encapsulation layer 600 including a plurality of encapsulation portions 610. At least part of the encapsulation portion 610 is located in the corresponding isolation opening 240 and located on a side of the corresponding light-emitting device 300 facing away from the substrate 100.

In these embodiments, at least part of the encapsulation portion 610 of the first encapsulation layer 600 is disposed in the isolation opening 240 to encapsulate the light-emitting device 300 in the isolation opening 240, thereby reducing the infiltration of moisture and oxygen into the light-emitting device 300, and prolonging the service life of the light-emitting device 300.

In some embodiments, at least part of the orthographic projection of the recessed portion 510 on the substrate 100 is located within an orthographic projection of the encapsulation portion 610 on the substrate 100.

In one embodiment, the orthographic projection of the recessed portion 510 on the substrate 100 is located within the orthographic projection of the encapsulation portion 610 on the substrate 100.

In these embodiments, the encapsulation portion 610 covers the region where the pixel opening 410 and the recessed portion 510 are located, to increase the coverage area of the encapsulation portion 610, thereby improving the encapsulation effect of the encapsulation portion 610. Moreover, the encapsulation portion 610 covers the entire recessed portion 510, and it is not necessary to specially shape the encapsulation portion 610, thereby simplifying the preparation process of the encapsulation portion 610, and reducing the difficulty of preparation of the encapsulation portion 610.

In one embodiment, a material of the first encapsulation layer 600 includes an inorganic material, which has good compactness and exhibits a good barrier property to moisture and oxygen.

In one embodiment, the display panel 10 further includes: a second encapsulation layer located on a side of the first encapsulation layer 600 facing away from the substrate 100; and a third encapsulation layer located on a side of the second encapsulation layer facing away from the substrate 100. With three-layer encapsulation, the display panel 10 exhibits a good encapsulation performance and reduces the possibility of moisture and oxygen infiltration.

In one embodiment, a material of the second encapsulation layer includes an organic material.

In one embodiment, a material of the third encapsulation layer includes an inorganic material. The first encapsulation layer 600, the second encapsulation layer, and the third encapsulation layer are respectively encapsulated with an inorganic material, an organic material, and an inorganic material to form a thin film encapsulation (TFE) structure, thereby further improving the encapsulation performance.

In some embodiments, the length of the second straight portion 511 is in the range of 5 μm to 10 μm. For example, the length of the second straight portion 511 is 5 μm, 6 μm, 7 μm, or 10 μm.

In these embodiments, the length of the second straight portion 511 being greater than or equal to 5 μm can alleviate the problem of interference between the first via hole 112 and the first light-emitting device 310 due to the fact that the length of the second straight portion 511 is too small and the dimension of the recessed portion 510 in the first direction X is thus too small and it is difficult to provide the first via hole 112 in the region where the recessed portion 510 is located. The length of the second straight portion 511 being less than or equal to 10 μm can alleviate the problem of a decrease in the area of the first pixel opening 411, a decrease in the light-emitting area of the first light-emitting device 310, and a decrease in the aperture ratio of the display panel 10 due to the fact that the length of the second straight portion 511 is too large and the dimension of the recessed portion 510 in the first direction X is thus too large and the recess area of the first pixel opening 411 is too large.

In some embodiments, the first dimension D1 is in the range of 10 μm to 20 μm. For example, the first dimension D1 is 10 μm, 12 μm, 14 μm, or 20 μm.

In these embodiments, the first dimension D1 being greater than or equal to 10 μm can alleviate the problem of a smaller area of the first pixel opening 411, a decrease in the area of the first light-emitting device 310, and a smaller aperture ratio of the display panel 10 due to the fact that the first dimension D1 is too small. The first dimension D1 being less than or equal to 20 μm can alleviate the problem of increased preparation difficulty caused by the too small distances between the first pixel opening 411 and the second pixel opening 412, and between the first pixel opening 411 and the third pixel opening 413 due to the fact that the dimension of the first pixel opening 411 in the second direction Y is too large.

In one embodiment, the light-emitting device 300 includes a lower electrode 301, a light-emitting functional structure 302 and an upper electrode 303 which are sequentially stacked in a direction away from the substrate 100. The upper electrode 303 is electrically connected to the isolation structure 200. One of the upper electrode 303 and the lower electrode 301 serves as an anode of the light-emitting functional structure 302 and the other serves as a cathode of the light-emitting functional structure 302. An embodiment of the present application is exemplified by taking the lower electrode 301 as the anode of the light-emitting functional structure 302, and the upper electrode 303 as the cathode of the light-emitting functional structure 302.

In some embodiments, an orthographic projection of the light-emitting functional structure 302 on the substrate 100 is located within an orthographic projection of the upper electrode 303 on the substrate 100.

In these embodiments, the orthographic projection of the light-emitting functional structure 302 on the substrate 100 is located within the orthographic projection of the upper electrode 303 on the substrate 100, that is, the upper electrode 303 is configured to cover the light-emitting functional structure 302 to serve as the electrode of the light-emitting functional structure 302 to ensure normal light emission of the light-emitting functional structure 302, thereby improving the display effect of the display panel 10.

In one embodiment, the light-emitting functional structures 302 are spaced apart from the isolation structure 200, the light-emitting functional structures 302 are spaced apart from the isolation structure 200, that is, the light-emitting functional structures 302 are spaced apart from each other, thereby reducing crosstalk of carriers between the light-emitting functional structures 302, and thus alleviating the problem of color mixing in the light-emitting functional structures 302.

In some embodiments, the isolation structure 200 includes a first layer 210 and a second layer 220 on a side of the first layer 210 facing away from the substrate 100, an orthographic projection of the first layer 210 on the substrate 100 being located within an orthographic projection of the second layer 220 on the substrate 100.

In these embodiments, the isolation structure 200 includes the first layer 210 and the second layer 220 on the side of the first layer 210 facing away from the substrate 100, the first layer 210 and the second layer 220 being stacked to form the isolation structure 200, an orthographic projection on the substrate 100 of the first layer 210 disposed close to the substrate 100 is located within an orthographic projection of the second layer 220 on the substrate 100, the area of the second layer 220 is greater than the area of the first layer 210, and the second layer 220 covers a surface of the first layer 210 close to the second layer 220, in which case the first layer 210 is recessed with respect to the second layer 220 in a direction away from the isolation opening 240. When a light-emitting layer 300 is prepared, the light-emitting layer 300 causes a large drop at an edge of the isolation structure 200, the first layer 210 is recessed relative to the second layer 220, and the light-emitting layer 300 is difficult to connect at the edge of the isolation structure 200, resulting in breakage. The light-emitting layer 300 breaks to form light-emitting devices 310 that are disconnected from each other, thereby reducing crosstalk of carriers in the light-emitting layer 300, and improving the display effect of the display panel 10; and the light-emitting device 310 may be prepared without the use of a precision mask, thereby reducing the development and use of the precision mask and lowering the preparation cost.

In one embodiment, the first layer 210 includes a conductive material, for example, the first layer 210 includes a non-metallic conductive material or a metallic conductive material.

In some embodiments, the second layer 220 includes a conductive material or an insulation material.

In these embodiments, the second layer 220 includes a conductive material, for example, the second layer 220 includes a non-metallic conductive material or a metallic conductive material. When the second layer 220 is made of a non-metallic conductive material or an insulation material, during wet etching of the first layer 210 with an etching solution, the second layer 220 is difficult to etch, thereby making it easier for the first layer 210 to be recessed relative to the second layer 220.

In some embodiments, the first layer 210 and the second layer 220 each include a metallic material, and the materials of the first layer 210 and the second layer 220 are different.

In these embodiments, when both the first layer 210 and the second layer 220 are made of the metallic material, the first layer 210 may be wet etched with an etching solution, and the etching solution is provided to enable an etching rate of the second layer 220 to be less than an etching rate of the first layer 210. Since the first layer 210 has a greater etching rate, when wet etching is performed with the etching solution, the first layer 210 is etched faster even though the second layer 220 is subjected to some etching, which causes the first layer 210 to be recessed relative to the second layer 220.

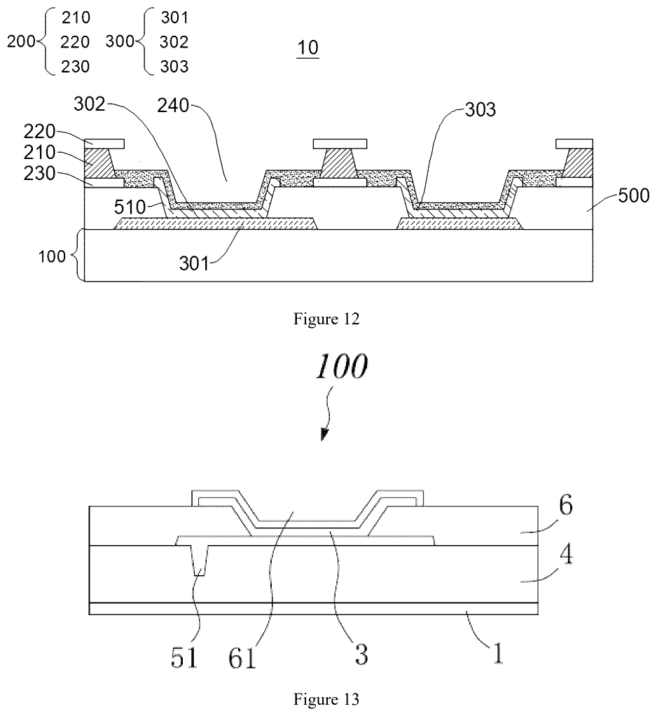

Referring to FIG. 12, FIG. 12 is a partial sectional view of a display panel according to still yet another embodiment.

As shown in FIG. 12, in some embodiments, the isolation structure 200 further includes a third layer 230 located on a side of the first layer 210 facing toward the substrate 100, an orthographic projection of the first layer 210 on the substrate 100 being located within an orthographic projection of the third layer 230 on the substrate 100.

In these embodiments, a large amount of waste is generated during the etching of the first layer 210 and is likely to enter other locations of the display panel 10, thus causing an adverse effect. After the third layer 230 is provided, the first layer 210 may be better adhered to the third layer 230, and the generated etching waste falls on the third layer 230 to facilitate removal.

In one embodiment, the material of the second layer 220 is titanium (Ti) or molybdenum (Mo), the material of the first layer 210 is aluminum (Al), silver (Ag) or copper (Cu), and the material of the third layer 230 is titanium (Ti) or molybdenum (Mo). For example, the material of the isolation structure 200 is a three-layer metal composite material of Ti/Al/Ti (titanium/aluminum/titanium) or Ti/Al/Mo (titanium/aluminum/molybdenum).

In one embodiment, the light-emitting functional structure 302 includes an electron injection layer (EIL), an electron transport layer (ETL), a light-emitting material layer, a hole injection layer (HIL), and a hole transport layer (HTL).

An embodiment of the present application provides a display panel 10. The display panel 10 includes: a substrate 100; a pixel defining layer 400 disposed on one side of the substrate 100, the pixel defining layer 400 having a plurality of pixel openings 410, the plurality of pixel openings 410 including first pixel openings 411, an edge of the first pixel opening 411 including a first straight portion 500 extending in a first direction X and a recessed portion 510 recessed toward the first straight portion 500, the recessed portion 510 including a second straight portion 511 close to the first straight portion 500, the first pixel opening 411 having a first dimension D1 in a second direction Y which intersects with the first direction X, and a length of the second straight portion 511 being less than the first dimension D1; an isolation structure 200 located on one side of the substrate 100, the isolation structure 200 enclosing a plurality of isolation openings 240, the isolation opening 240 being in communication with the corresponding pixel opening 410; and a plurality of light-emitting devices 300, the plurality of light-emitting devices 300 including a plurality of first light-emitting devices 310, part of the first light-emitting device 310 being disposed in the corresponding first pixel opening 411.

According to the display panel 10 of the embodiment of the present application, the display panel 10 includes the substrate 100, the pixel defining layer 400, and the light-emitting devices 300. The pixel defining layer 400 has a plurality of pixel openings 410 to define light-emitting regions of the display panel 10. The plurality of pixel openings 410 include the first pixel openings 411. The edge of the first pixel opening 411 includes the first straight portion 500 extending in the first direction X and the recessed portion 510 recessed toward the first straight portion 500. The recessed portion 510 includes the second straight portion 511 close to the first straight portion 500. The first pixel opening 411 is configured so two sides of the recessed portion 510 in the first direction X protrude in a direction away from the first straight portion 500, to increase an area of the first pixel opening 411, thereby increasing a light-emitting area of a light-emitting device and an aperture ratio of the display panel 10. When the light-emitting device 300 is prepared, a light-emitting material layer has a large drop at an edge of the isolation structure 200, and is difficult to be continuous, resulting in breakage. The light-emitting material layer breaks to form light-emitting functional structures 302 located in the isolation openings 240, thereby reducing crosstalk of carriers in the light-emitting functional structures 302, and improving the display effect of the display panel 10. In addition, the light-emitting devices 300 can be prepared without the use of a precision mask, thereby reducing the development and use of the precision mask and lowering the preparation cost. The length of the second straight portion 511 is less than the first dimension D1 so the first pixel opening 411 is recessed to a smaller extent toward the first straight portion 500, ensuring that the first pixel opening 411 has a larger area, that is, the first light-emitting device 310 has a larger light-emitting area, thereby further improving the aperture ratio and the display effect of the display panel 10, and thus improving the performance of OLED display products.

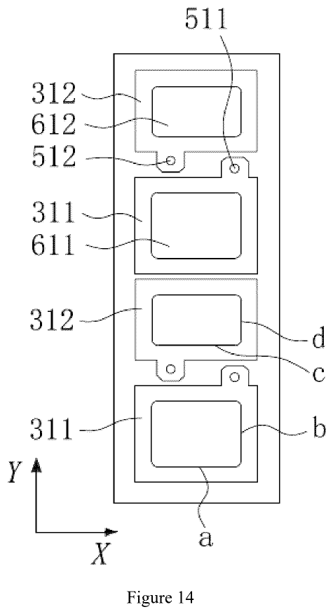

Referring to FIGS. 13-14, an embodiment of the present application discloses a display panel 100, including a substrate 1, a drive circuit layer 4, a pixel definition layer 6, and a plurality of light-emitting devices 3.

The drive circuit layer 4 is disposed on one side of the substrate 1. The drive circuit layer 4 is provided with a plurality of pixel drive units and a plurality of via holes 51. The plurality of pixel drive units include a plurality of third pixel drive units and a plurality of second pixel drive units, and the via holes 51 include a plurality of third via holes 511 and a plurality of second via holes 512.

The pixel definition layer 6 is disposed on a side of the drive circuit layer 4 away from the substrate 1. The pixel definition layer 6 defines a plurality of pixel openings 61. The plurality of pixel openings 61 include a plurality of third pixel openings 611 and a plurality of second pixel openings 612.

The plurality of light-emitting devices 3 include a plurality of third light-emitting devices and a plurality of second light-emitting devices. The third light-emitting device is partially disposed in the corresponding third pixel opening 611 and is electrically connected to the corresponding third pixel drive unit by means of the corresponding third via hole 511, and the second light-emitting device is partially disposed in the corresponding second pixel opening 612 and is electrically connected to the corresponding second pixel drive unit by means of the corresponding second via hole 512.

The orthographic projection of the third via hole 511 and the second via hole 512 on the substrate 1 is located between the orthographic projection of the corresponding third pixel opening 611 on the substrate 1 and the orthographic projection of the corresponding second pixel opening 612 on the substrate 1.

In the display panel 100 according to this embodiment, the orthographic projection of the third via hole 511 and the second via hole 512 on the substrate 1 being between the orthographic projection of the corresponding third pixel opening 611 on the substrate 1 and the orthographic projection of the corresponding second pixel opening 612 on the substrate 1 facilitates the compression of the space outside the pixel openings 61, thereby increasing a pixel aperture ratio, enhancing the brightness of the display panel 100, and improving the display performance of the display panel 100.

With continued reference to FIG. 14, in one embodiment, an edge of the third pixel opening 611 includes a first long edge a, and an edge of the second pixel opening 612 includes a second long edge c, a straight line on which the first long edge a lies being parallel to a straight line on which the second long edge c lies, thereby facilitating an increase in the pixel aperture ratio.

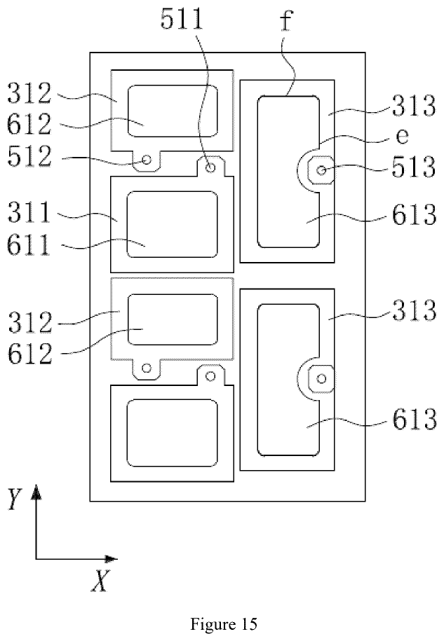

Referring to FIG. 15, in one embodiment, the plurality of pixel openings 61 further include a plurality of first pixel openings 613, an edge of the first pixel opening 613 including a third long edge e, a straight line on which the third long edge e lies being parallel to the straight line on which the first long edge a lies.

In one embodiment, the straight line on which the third long edge e lies is perpendicular to the straight line on which the first long edge a lies.

In one embodiment, the edge of the third pixel opening 611 further includes a first short edge b connected to the first long edge a, and the edge of the second pixel opening 612 further includes a second short edge d connected to the second long edge c, a straight line on which the first short edge b lies being parallel to a straight line on which the second short edge d lies, thereby facilitating an increase in the pixel aperture ratio. The first long edge a and the first short edge b enclose the third pixel opening 611, and the length of the first long edge a is greater than the length of the first short edge b; and the second long edge c and the second short edge d enclose the second pixel opening 612, and the length of the second long edge c is greater than the length of the second short edge d.

In one embodiment, the edge of the first pixel opening 613 further includes a third short edge f connected to the third long edge e, a straight line on which the third short edge f lies intersecting with the straight line on which the first short edge b lies. The third long edge e and the third short edge f enclose the first pixel opening 613, and the length of the third long edge e is greater than the length of the third short edge f.

In one embodiment, the straight line on which the third short edge f lies is perpendicular to the straight line on which the first short edge b lies.

In one embodiment, the straight line on which the third short edge f lies is parallel to the straight line on which the first long edge a lies, and/or the straight line on which the third long edge f lies is parallel to the straight line on which the first short edge b lies.

With continued reference to FIG. 15, in one embodiment, an opening area of the first pixel opening 613 is greater than an opening area of the third pixel opening 611, or the opening area of the first pixel opening 613 is greater than an opening area of the second pixel opening 612. Further, the opening area of the first pixel opening 613 is greater than the opening area of the third pixel opening 611 and the opening area of the second pixel opening 612.

In one of the embodiments, the light-emitting color of the third light-emitting device is different from the light-emitting color of the second light-emitting device, thereby improving the richness of display.

In one embodiment, the plurality of light-emitting devices 3 further include a plurality of first light-emitting devices. The first light-emitting device is disposed in the corresponding first pixel openings 613. The light-emitting color of the third light-emitting device, the light-emitting color of the second light-emitting device and a light-emitting color of the first light-emitting device are different from one another, thereby improving the richness of display.

In one embodiment, the light-emitting color of the third light-emitting device is either red or green, the light-emitting color of the second light-emitting device is the other of red and green, and the light-emitting color of the first light-emitting device is blue.

In one embodiment, the plurality of light-emitting devices 3 further include a plurality of first light-emitting devices. Part of the first light-emitting device is disposed in the corresponding first pixel opening 613.

Referring to FIG. 15, in one embodiment, the display panel 100 includes a plurality of first pixel columns and a plurality of second pixel columns which are arranged alternately in a second direction (e.g., the X-direction in the figure). The first pixel column includes a plurality of third light-emitting devices and a plurality of second light-emitting devices which are arranged alternately in a first direction (e.g., the Y-direction in the figure), and the second pixel column includes a plurality of first light-emitting devices arranged in the first direction. The second direction intersects with the first direction.

The second direction may be at 70 degrees, 80 degrees, 85 degrees, etc. relative to the first direction. In one embodiment, the second direction is perpendicular to the first direction.

In one embodiment, the straight line on which the first long edge a lies is parallel to the second direction, and the straight line on which the second long edge c lies is parallel to the second direction.

In one embodiment, the straight line on which the third long edge e lies is parallel to the first direction.

In one embodiment, the straight line on which the first short edge b lies is parallel to the first direction, and/or the straight line on which the second short edge d lies is parallel to the first direction.

In one embodiment, the straight line on which the third short edge f lies is parallel to the second direction.

In one embodiment, a length of the third long edge e is greater than a length of the first long edge a, and/or the length of the third long edge e is greater than a length of the second long edge c.

In one embodiment, the length of the first long edge a is equal to the length of the second long edge c.

In one embodiment, the length of the first long edge a is greater than a length of the first short edge b, and/or the length of the second long edge c is greater than a length of the second short edge d, and/or the length of the third long edge e is greater than a length of the third short edge f.

In one embodiment, the edge of the third pixel opening 611 includes a plurality of first edges, the plurality of first edges including the first long edge a and the first short edge b, the first long edge a being a first edge having a longest length among the plurality of first edges; and/or
the edge of the second pixel opening 612 includes a plurality of second edges, the plurality of second edges including the second long edge c and the second short edge d, the second long edge c being a second edge having a longest length among the plurality of second edges; and/or
the edge of the first pixel opening 613 includes a plurality of third edges, the plurality of third edges including the first straight portion, the recessed portion, the third long edge e and the third short edge f, the third long edge e being a third edge having a longest length among the plurality of third edges.

In one embodiment, the plurality of light-emitting devices 3 further include a plurality of first light-emitting devices. Part of the first light-emitting device is disposed in the corresponding first pixel opening 613.

The display panel 100 includes a plurality of pixels arranged in an array, the pixel including the third light-emitting device, the second light-emitting device and the first light-emitting device. In the same pixel, the orthographic projection on the substrate 1 of the third via hole 511 corresponding to the third light-emitting device and the second via hole 512 corresponding to the second light-emitting device is located between the orthographic projection on the substrate 1 of the third pixel opening 611 corresponding to the third light-emitting device and the orthographic projection on the substrate 1 of the second pixel opening 612 corresponding to the second light-emitting device, thereby facilitating an increase in the pixel aperture ratio.

In one embodiment, in the same pixel, the third light-emitting device and the first light-emitting device are arranged in the second direction which intersects with the first direction, the second light-emitting device and the first light-emitting device are arranged in the second direction, and the third light-emitting device and the second light-emitting device are arranged in the first direction.

In one embodiment, the second direction is perpendicular to the first direction.

In one embodiment, in the same pixel, the third light-emitting device and the second light-emitting device are on the same side of the first light-emitting device.

In one embodiment, the straight line on which the first long edge a lies is parallel to the second direction, and the straight line on which the second long edge c lies is parallel to the second direction.

In one embodiment, the straight line on which the third long edge e lies is parallel to the first direction.

In one embodiment, the straight line on which the first short edge b lies is parallel to the first direction, and/or the straight line on which the second short edge d lies is parallel to the first direction.

In one embodiment, the straight line on which the third short edge f lies is parallel to the second direction.

In one embodiment, a length of the third long edge e is greater than a length of the first long edge a, and/or the length of the third long edge e is greater than a length of the second long edge c.

In one embodiment, the length of the first long edge a is equal to the length of the second long edge c.

Due to process constraints, the third pixel opening 611 has a third shortest distance from the second pixel opening 612, leaving room for the third via hole 511 and the second via hole 512. In one embodiment, a sum of the third shortest distance, a length of the first short edge b and the length of the second long edge c is greater than the length of the third long edge e, and/or a sum of the third shortest distance, the length of the first long edge a and a length of the second short edge b is greater than the length of the third long edge e, facilitating the compression of the space outside the pixel openings, thereby increasing the pixel aperture ratio. In one embodiment, the third shortest distance is in the range of 16-28 um, such as 16 um, 18 um, 20 um, 24 um, 28 um, etc., without specific limitation.

In one embodiment, a ratio of the length of the first long edge a to the length of the first short edge b is in the range of 1.1-3, facilitating the compression of the space outside the pixel openings, thereby increasing the pixel aperture ratio. By way of example, the ratio of the length of the first long edge a to the length of the first short edge b is 1.1, 1.2, 1.5, 2, 2.5, 3, etc., without specific limitation.

In one embodiment, a ratio of the length of the second long edge c to the length of the second short edge d is 1.1-3, facilitating the compression of the space outside the pixel openings, thereby increasing the pixel aperture ratio. By way of example, the ratio of the length of the second long edge c to the length of the second short edge d is 1.1, 1.2, 1.5, 2, 2.5, 3, etc., without specific limitation.

As for the structural design in this embodiment, it can be applied to other display panels 10, which can be selected according to actual situations, and this is not specifically limited in the present application.

An embodiment of the present application further provides a display apparatus including a display panel 10 of any one of the above embodiments. Since the display apparatus according to the embodiment of the present application includes the display panel 10 of any one of the above embodiments, the display apparatus according to the embodiment of the present application has the beneficial effects of the display panel 10 of any one of the above embodiments, which will not be described in detail here.

The display apparatus in the embodiments of the present application includes, but is not limited to, devices having a display function, such as a mobile phone, a personal digital assistant (PDA), a tablet computer, an e-book reader, a television, an access control system, a smart fixed-line telephone, or a console.

The embodiments of the present application as described above neither set forth all the details, nor do they limit the present application to only the described specific embodiments. Apparently, many modifications and variations can be made in light of the above description. The embodiments are selected and described in this specification to better explain the principles and practical applications of the present application, and good use of the present application can be made and modify and use the present application. The present application is limited only by the claims and all the scopes and equivalents thereof.

What is claimed is:

1. A display panel, comprising:
a substrate;
a pixel defining layer disposed on one side of the substrate, the pixel defining layer having a plurality of pixel openings, the plurality of pixel openings comprising a plurality of first pixel openings, an edge of the first pixel opening comprising a first straight portion extending in a first direction and a recessed portion recessed toward the first straight portion, the recessed portion comprising a second straight portion close to the first straight portion, the first pixel opening having a first dimension in a second direction which intersects with the first direction, and a length of the second straight portion being less than the first dimension; and
a plurality of light-emitting devices comprising a plurality of first light-emitting devices, part of the first light-emitting device being disposed in the corresponding first pixel opening.

2. The display panel according to claim 1, wherein the edge of the first pixel opening further comprises a fifth straight portion and a sixth straight portion located on a side of the second straight portion away from the first straight portion, and the display panel further comprises:
a drive circuit layer disposed between the substrate and the pixel defining layer, the drive circuit layer having a plurality of first pixel drive units and a plurality of first via holes, the first light-emitting device partially extending to the corresponding first via hole and being electrically connected to the corresponding first pixel drive unit,
wherein at least part of an orthographic projection of the second straight portion on the substrate is located between an orthographic projection of the first straight portion on the substrate and an orthographic projection of the first via hole on the substrate; or part of the orthographic projection of the first via hole on the substrate is located between an orthographic projection of the fifth straight portion on the substrate and an orthographic projection of the sixth straight portion on the substrate; or at least part of the orthographic projection of the second straight portion on the substrate is located between the orthographic projection of the first straight portion on the substrate and the orthographic projection of the first via hole on the substrate, and part of the orthographic projection of the first via hole on the substrate is located between the orthographic projection of the fifth straight portion on the substrate and the orthographic projection of the sixth straight portion on the substrate.

3. The display panel according to claim 1, wherein the second straight portion has a length in the range of 5 μm to 10 μm, and/or the first dimension has a value in the range of 10 μm to 20 μm.

4. The display panel according to claim 2, wherein the first straight portion is parallel to the second straight portion, the fifth straight portion is parallel to the first straight portion, the sixth straight portion is parallel to the first straight portion, and the first direction is perpendicular to the second direction;
the recessed portion further comprises a third straight portion and a first curved portion, the first curved portion being connected to a first end of the second straight portion and a first end of the third straight portion, and an included angle between the second straight portion and the third straight portion being not less than 90 degrees;
the recessed portion further comprises a fourth straight portion and a second curved portion, the second curved portion being connected to a second end of the second straight portion and a first end of the fourth straight portion, and an included angle between the second straight portion and the fourth straight portion being not less than 90 degrees;
the edge of the first pixel opening further comprises a third curved portion and a fourth curved portion, wherein the third curved portion is connected to a second end of the third straight portion and a first end of the fifth straight portion, an included angle between the third straight portion and the fifth straight portion is not less than 90 degrees, the fourth curved portion is connected to a second end of the fourth straight portion and a first end of the sixth straight portion, and an included angle between the fourth straight portion and the sixth straight portion is not less than 90 degrees; and
the third straight portion and the fourth straight portion are located on the side of the second straight portion away from the first straight portion.

5. The display panel according to claim 4, wherein the edge of the first pixel opening further comprises a seventh straight portion, an eighth straight portion, a fifth curved portion, a sixth curved portion, a seventh curved portion and an eighth curved portion, wherein the fifth curved portion is connected to a first end of the first straight portion and a first end of the seventh straight portion, the sixth curved portion is connected to a second end of the seventh straight portion and a second end of the fifth straight portion, and the seventh straight portion extends in the second direction;
the seventh curved portion is connected to a second end of the first straight portion and a first end of the eighth straight portion, the eighth curved portion is connected to a second end of the eighth straight portion and a second end of the sixth straight portion, and the eighth straight portion extends in the second direction;
the length of the second straight portion is less than a length of the seventh straight portion;
a length of the first straight portion is greater than the length of the seventh straight portion;
an included angle between the seventh straight portion and the first straight portion is not less than 90 degrees, and an included angle between the seventh straight portion and the fifth straight portion is not less than 90 degrees;
the length of the second straight portion is less than a length of the eighth straight portion;
the length of the first straight portion is greater than the length of the eighth straight portion;
an included angle between the eighth straight portion and the first straight portion is not less than 90 degrees, and an included angle between the eighth straight portion and the sixth straight portion is not less than 90 degrees; and
the length of the seventh straight portion is less than the first dimension, and the length of the eighth straight portion is less than the first dimension.

6. The display panel according to claim 1, wherein the plurality of pixel openings further comprise a plurality of second pixel openings and a plurality of third pixel openings, and the plurality of light-emitting devices further comprise a plurality of second light-emitting devices and a plurality of third light-emitting devices, part of the second light-emitting device being disposed in the corresponding second pixel opening, and part of the third light-emitting device being disposed in the corresponding third pixel opening; and the display panel further comprises:
a drive circuit layer disposed between the substrate and the pixel defining layer and provided with a plurality of pixel drive units and a plurality of via holes, the plurality of pixel drive units comprising a plurality of first pixel drive units, a plurality of second pixel drive units, and a plurality of third pixel drive units, and the plurality of via holes comprising a plurality of first via holes, a plurality of second via holes, and a plurality of third via holes,
wherein the first light-emitting device partially extends to the corresponding first via hole and is electrically connected to the corresponding first pixel drive unit, the second light-emitting device partially extends to the corresponding second via hole and is electrically connected to the corresponding second pixel drive unit, and the third light-emitting device partially extends to the corresponding third via hole and is electrically connected to the corresponding third pixel drive unit; and
an orthographic projection of the second via hole and the third via hole on the substrate is located between an orthographic projection of the corresponding second pixel opening on the substrate and an orthographic projection of the corresponding third pixel opening on the substrate.

7. The display panel according to claim 6, wherein an edge of the third pixel opening comprises a first long edge, and an edge of the second pixel opening comprises a second long edge, a straight line on which the first long edge lies being parallel to a straight line on which the second long edge lies;
the edge of the first pixel opening further comprises a third long edge, a straight line on which the third long edge lies being perpendicular to the straight line on which the first long edge lies;
the edge of the third pixel opening further comprises a first short edge connected to the first long edge, and the edge of the second pixel opening further comprises a second short edge connected to the second long edge, a straight line on which the first short edge lies being parallel to a straight line on which the second short edge lies; the edge of the first pixel opening further comprises a third short edge connected to the third long edge, a straight line on which the third short edge lies being perpendicular to the straight line on which the first short edge lies; and
the straight line on which the third short edge lies is parallel to the straight line on which the first long edge lies, and the straight line on which the third long edge lies is parallel to the straight line on which the first short edge lies.

8. The display panel according to claim 7, further comprising:
a plurality of first pixel columns and a plurality of second pixel columns which are arranged alternately in the second direction, the first pixel column comprising a plurality of third light-emitting devices and a plurality of second light-emitting devices which are arranged alternately in the first direction, and the second pixel column comprising a plurality of first light-emitting devices arranged in the first direction which is perpendicular to the second direction;
wherein the straight line on which the first long edge lies is parallel to the second direction, and the straight line on which the second long edge lies is parallel to the second direction;
the straight line on which the third long edge lies is parallel to the first direction; the straight line on which the first short edge lies is parallel to the first direction, and the straight line on which the second short edge lies is parallel to the first direction; and
the straight line on which the third short edge lies is parallel to the second direction.

9. The display panel according to claim 7, wherein a length of the third long edge is greater than a length of the first long edge and the length of the third long edge is greater than a length of the second long edge;
the length of the first long edge is greater than a length of the first short edge, the length of the second long edge is greater than a length of the second short edge, and the length of the third long edge is greater than a length of the third short edge;
the edge of the third pixel opening comprises a plurality of first edges, the plurality of first edges comprising the first long edge and the first short edge, the first long edge being a first edge having a longest length among the plurality of first edges; the edge of the second pixel opening comprises a plurality of second edges, the plurality of second edges comprising the second long edge and the second short edge, the second long edge being a second edge having a longest length among the plurality of second edges; and
the edge of the first pixel opening comprises a plurality of third edges, the plurality of third edges comprising the first straight portion, the recessed portion, the third long edge and the third short edge, the third long edge being a third edge having a longest length among the plurality of third edges.

10. The display panel according to claim 7, further comprising:
a plurality of pixels arranged in an array, the pixel comprising the third light-emitting device, the second light-emitting device and the first light-emitting device; wherein in the same pixel, the orthographic projection on the substrate of the third via hole corresponding to the third light-emitting device and the second via hole corresponding to the second light-emitting device is located between the orthographic projection on the substrate of the third pixel opening corresponding to the third light-emitting device and the orthographic projection on the substrate of the second pixel opening corresponding to the second light-emitting device; and
in the same pixel, the third light-emitting device and the first light-emitting device are arranged in the second direction which intersects with the first direction, the second light-emitting device and the first light-emitting device are arranged in the second direction, and the third light-emitting device and the second light-emitting device are arranged in the first direction.

11. The display panel according to claim 10, wherein in the same pixel, the third light-emitting device and the second light-emitting device are on the same side of the first light-emitting device;
the straight line on which the first long edge lies is parallel to the second direction, and the straight line on which the second long edge lies is parallel to the second direction;
the straight line on which the third long edge lies is parallel to the first direction; the straight line on which the first short edge lies is parallel to the first direction, and the straight line on which the second short edge lies is parallel to the first direction; and
the straight line on which the third short edge lies is parallel to the second direction.

12. The display panel according to claim 7, wherein a length of the third long edge is greater than a length of the first long edge and the length of the third long edge is greater than a length of the second long edge;
the third pixel opening and the second pixel opening have a third shortest distance defined therebetween, a sum of the third shortest distance, a length of the first short edge and the length of the second long edge is greater than the length of the third long edge, and/or a sum of the third shortest distance, the length of the first long edge and a length of the second short edge is greater than the length of the third long edge;
the third shortest distance is in the range of 16-28 um;
a ratio of the length of the first long edge to the length of the first short edge is in the range of 1.1-3; and
a ratio of the length of the second long edge to the length of the second short edge is in the range of 1.1-3.

13. The display panel according to claim 7, wherein a light-emitting color of the third light-emitting device is one of red and green, a light-emitting color of the second light-emitting device is the other of red and green, and a light-emitting color of the first light-emitting device is blue; and
an opening area of the first pixel opening is greater than an opening area of the third pixel opening; or the opening area of the first pixel opening is greater than an opening area of the second pixel opening; or the opening area of the first pixel opening is greater than the opening area of the third pixel opening, and the opening area of the first pixel opening is greater than the opening area of the second pixel opening.

14. The display panel according to claim 1, wherein the plurality of pixel openings further comprise a plurality of second pixel openings and a plurality of third pixel openings, and the plurality of light-emitting devices further comprise a plurality of second light-emitting devices and a plurality of third light-emitting devices, wherein
an edge of the second pixel opening comprises a plurality of ninth straight portions and a plurality of ninth curved portions, the ninth curved portion being connected between two corresponding adjacent ninth straight portions, and an included angle between two adjacent ninth straight portions being not less than 90 degrees;
part of the second light-emitting device is disposed in the corresponding second pixel opening, and a light-emitting color of the second light-emitting device is different from a light-emitting color of the first light-emitting device;
an edge of the third pixel opening comprises a plurality of tenth straight portions and a plurality of tenth curved portions, the tenth curved portion being connected between two corresponding adjacent tenth straight portions, and an included angle between two adjacent tenth straight portions being not less than 90 degrees;
part of the third light-emitting device is disposed in the corresponding third pixel opening, and the light-emitting color of the first light-emitting device, the light-emitting color of the second light-emitting device, and a light-emitting color of the third light-emitting device are different from one another; and
the recessed portion is located on a side of the first straight portion away from the second pixel opening, and is located on a side of the first straight portion away from the third pixel opening.

15. The display panel according to claim 14, wherein a length of the first straight portion is greater than a length of the ninth straight portion and the length of the first straight portion is greater than a length of the tenth straight portion.

16. The display panel according to claim 14, wherein the second straight portion has a first shortest distance from a ninth straight portion, which is close to the second straight portion, extends in the first direction, and in a pixel adjacent to the second straight portion in the second direction;
the first straight portion has a second shortest distance from a ninth straight portion, which is close to the first straight portion, extends in the first direction, and in the same pixel; and
the first shortest distance being not less than the second shortest distance.

17. The display panel according to claim 16, wherein
the length of the second straight portion is less than or equal to one half of the first dimension; or
the length of the second straight portion is less than or equal to one third of a length of the first straight portion; or
the length of the second straight portion is less than or equal to one half of the first dimension, and the length of the second straight portion is less than or equal to one third of the length of the first straight portion.

18. The display panel according to claim 1, further comprising:
an isolation structure located on a side of the pixel defining layer facing away from the substrate, the isolation structure enclosing a plurality of isolation openings, the isolation opening being in communication with the corresponding pixel opening, and the isolation structure comprising a first layer, a second layer, and a third layer, wherein the second layer is located on a side of the first layer facing away from the substrate, the third layer is located on a side of the first layer facing toward the substrate, an orthographic projection on the substrate of a side of the first layer close to the second layer is located within an orthographic projection of the second layer on the substrate, and an orthographic projection of the first layer on the substrate is located within an orthographic projection of the third layer on the substrate;
wherein the light-emitting device comprises a lower electrode, a light-emitting functional structure and an upper electrode sequentially stacked in a direction away from the substrate, the upper electrode being electrically connected to the isolation structure, an orthographic projection of the light-emitting functional structure on the substrate being located within an orthographic projection of the upper electrode on the substrate, and the light-emitting functional structure being spaced apart from the isolation structure.

19. The display panel according to claim 1, further comprising:
a first encapsulation layer comprising a plurality of encapsulation portions, at least part of the encapsulation portion being located in the corresponding isolation opening and located on a side of the corresponding light-emitting device facing away from the substrate;
a second encapsulation layer located on a side of the first encapsulation layer facing away from the substrate; and
a third encapsulation layer located on a side of the second encapsulation layer facing away from the substrate,
wherein a material of the first encapsulation layer comprises an inorganic material, a material of the second encapsulation layer comprises an organic material, and a material of the third encapsulation layer comprises an inorganic material.

20. A display apparatus, comprising:
a display panel, comprising:
a substrate;
a pixel defining layer disposed on one side of the substrate, the pixel defining layer having a plurality of pixel openings, the plurality of pixel openings comprising a plurality of first pixel openings, an edge of the first pixel opening comprising a first straight portion extending in a first direction and a recessed portion recessed toward the first straight portion, the recessed portion comprising a second straight portion close to the first straight portion, the first pixel opening having a first dimension in a second direction which intersects with the first direction, and a length of the second straight portion being less than the first dimension; and
a plurality of light-emitting devices comprising a plurality of first light-emitting devices, part of the first light-emitting device being disposed in the corresponding first pixel opening.
